(19) United States
(12) Patent Application Publication
(10) Pub. No.: US 2012/0248533 A1
(43) Pub. Date: Oct. 4, 2012

(54) FIELD PLATE AND CIRCUIT THEREWITH

(76) Inventors: Rob Van Dalen, Bergeijk (NL); Anco Heringa, Waalre (NL)

(21) Appl. No.: 13/079,590

(22) Filed: Apr. 4, 2011

(51) Int. Cl. H01L 29/78; H01L 21/765

(52) U.S. Cl. 257/337; 438/454; 257/E29.256; 257/E21.574

(57) ABSTRACT

A circuit having a field plate is provided. In accordance with one or more embodiments, an electronic device includes a substrate having an active region, and a contiguous field plate separated from the active region by a dielectric material on the substrate. The field plate has first and second end regions (e.g., opposing one another along a length of the field plate), with the second end region being patterned. The patterned end region has at least one opening therein as defined by edges of the field plate (e.g., along an outer perimeter and/or as an internal opening), and couples a field to the active region in response to a voltage applied to the field plate. This field is greater in strength near the first end region, relative to the patterned end region.

Various aspects of the present invention are directed to circuits, and more particularly to semiconductor circuits including field plates.

Field plates are used in a variety of electrical applications, and have been particularly useful in high voltage (HV) semiconductor devices. Field plates often include a conducting layer at a known potential (e.g., metal or polysilicon connected to source, gate, drain, ground, cathode or anode), that is electrically separated from the underlying active silicon by a dielectric. Such field plates can be used to shield external disturbances (aiding stability), and to shape the electric field distribution/profile within devices. Field plates have been successfully used to improve the blocking capability of pn-junctions in devices such as discrete or integrated pn-diodes, bipolar transistors, MOSFETs and other devices.

For a variety of applications, an underlying dielectric having a thickness below the field plate that increases gradually when moving from source towards drain is quite attractive. However, this arrangement can be technologically challenging to achieve. Single thickness dielectrics are incapable of achieving desirable properties as otherwise obtained using an increasing thickness. Multi-step approximations have been used in lieu of a gradually increasing thickness, but are susceptible to undesirable electric field peaks at each transition, and generally require additional undesirable manufacturing steps.

Accordingly, the implementation of field plates for a variety of applications continues to be challenging.

Various example embodiments are directed to field plate-based circuits for a variety of applications and addressing various challenges, including those discussed above.

Various embodiments are directed to devices, methods and systems employing field plates. In connection with an example embodiment, a circuit device includes a substrate having an active region, a dielectric material on the substrate and a contiguous field plate separated from the substrate by the dielectric material. The field plate has first and second end regions, with the second end region being patterned with at least one opening therein defined by edges of the field plate. The field plate couples a field to the active region in response to a voltage applied to the field plate, with the field coupled to the active region via the second end region having a lower strength relative to the field coupled to the active region via the first end region.

Another embodiment is directed to an integrated circuit device including a semiconductor substrate having a current path therein, including source/drain electrodes separated by a channel region. The device includes a dielectric material on the substrate and a gate on the dielectric material and laterally adjacent one of the source/drain electrodes. The gate is configured to apply a bias to the channel region adjacent the one of the source/drain electrodes. The device also includes a contiguous field plate having first and second end regions, the first end region being adjacent to the gate and the second end region being patterned and having at least one opening therein defined by edges of the field plate. The gate, which can be contiguously linked with the field plate, couples a field to the channel region in response to a voltage applied thereto, biasing the channel to flow current between the source/drain regions (e.g., directly and via the field plate). The field coupled to the active region via the second end region has a lower strength relative to the field coupled to the active region via the first end region, as set via the patterning of the second end region.

In accordance with another example embodiment, an integrated circuit device is manufactured as follows. An active region is formed in a semiconductor substrate, and a dielectric layer is formed on the substrate. A contiguous field plate is formed on the dielectric layer and extending from a first end region to a second end region, by defining at least one opening in the second end region. The opening is defined to configure the field plate to, in response to a voltage applied to the field plate, couple a field to the active region via the first and second end regions with the field applied via the second end region having a lower strength relative to the field coupled to the active region via the first end region.

The above discussion is not intended to describe each embodiment or every implementation of the present disclosure. The figures and following description also exemplify various embodiments.

Various example embodiments may be more completely understood in consideration of the following detailed description in connection with the accompanying drawings, in which:

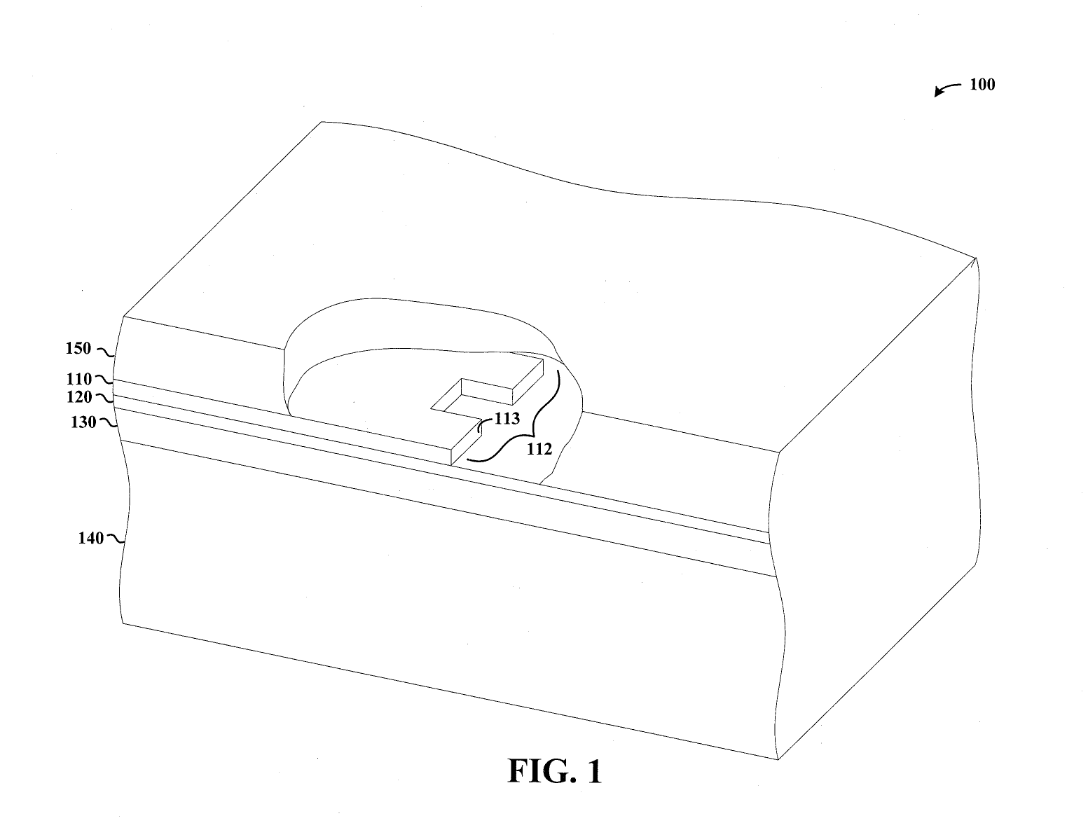

FIG. 1 shows a cross-sectional view of a semiconductor device 100 with a patterned field plate 110, according to an example embodiment of the present invention;

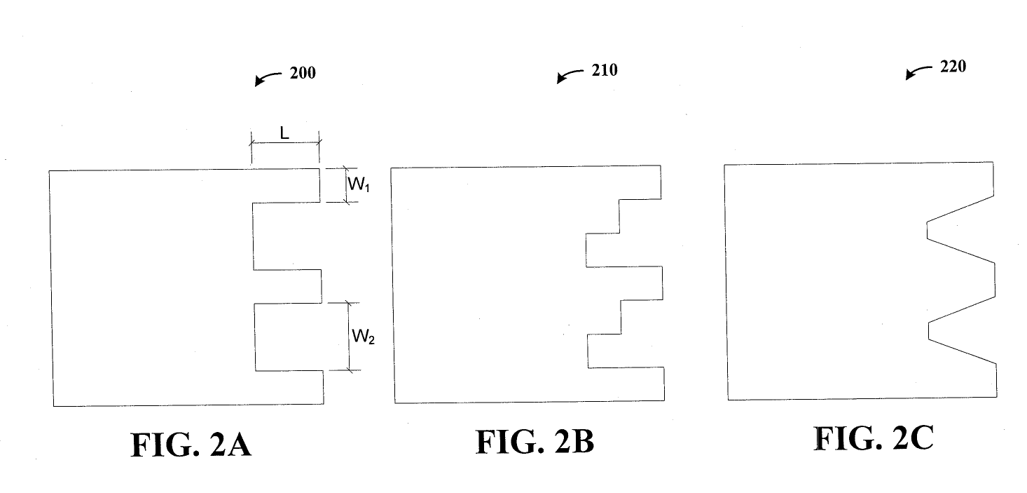

FIG. 2 shows patterned field plates, according to another example embodiment of the present invention;

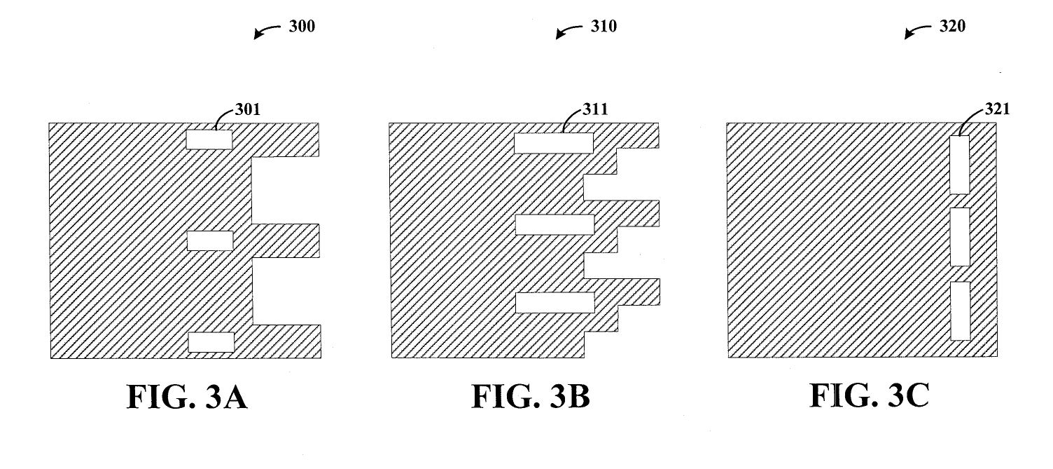

FIG. 3 shows patterned field plates with openings therein, according to another example embodiment of the present invention;

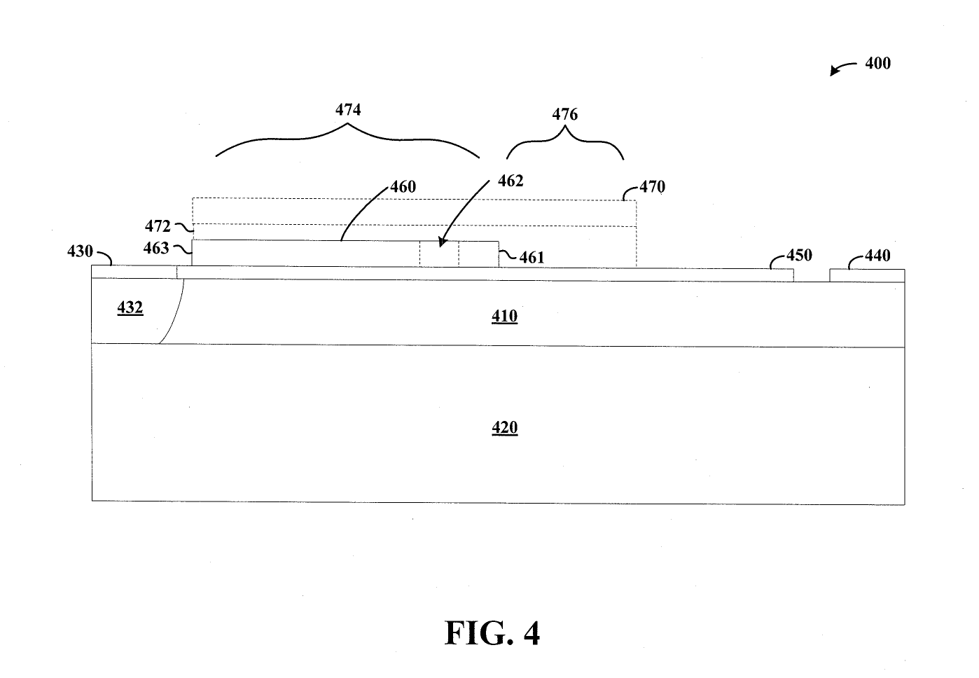

FIG. 4 shows a circuit device having a field plate to effect a varied field upon an active region, in accordance with another example embodiment of the present invention;

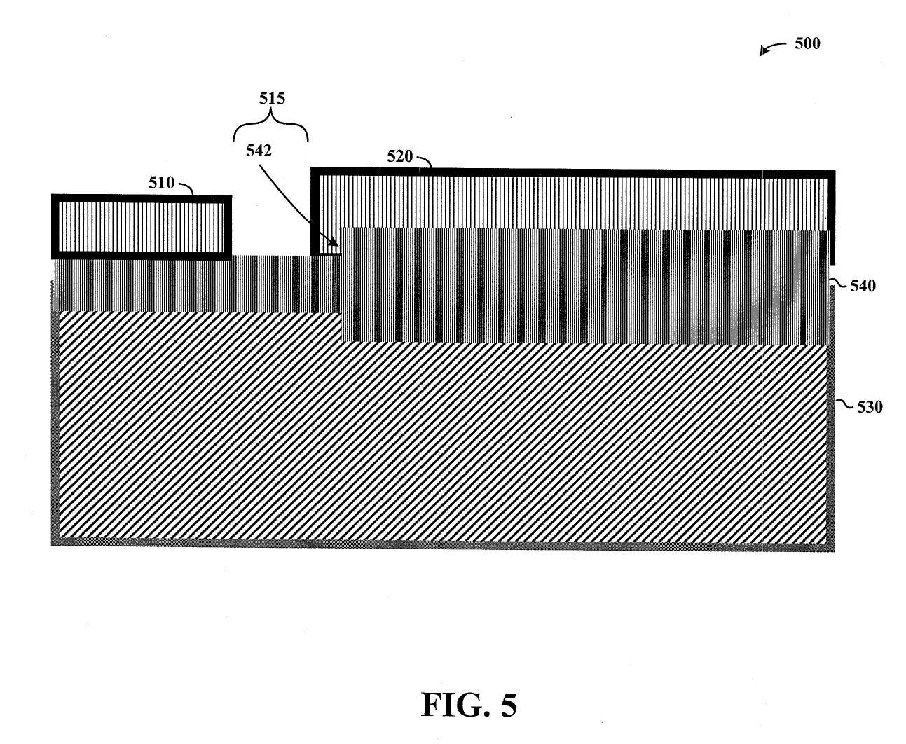

FIG. 5 shows a cross-sectional view of a field plate device having an opening patterned in a field plate and offset from an underlying dielectric transition, in accordance with another example embodiment of the present invention;

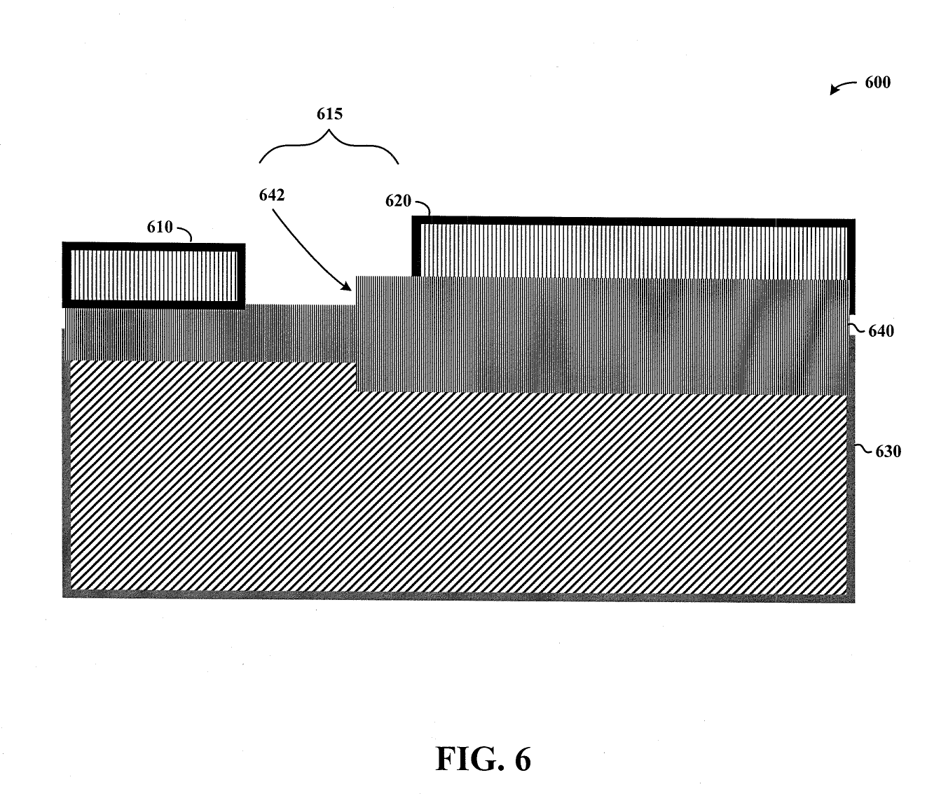

FIG. 6 shows a cross-sectional view of a field plate device having an opening patterned in a field plate and over an underlying dielectric transition, in accordance with another example embodiment of the present invention;

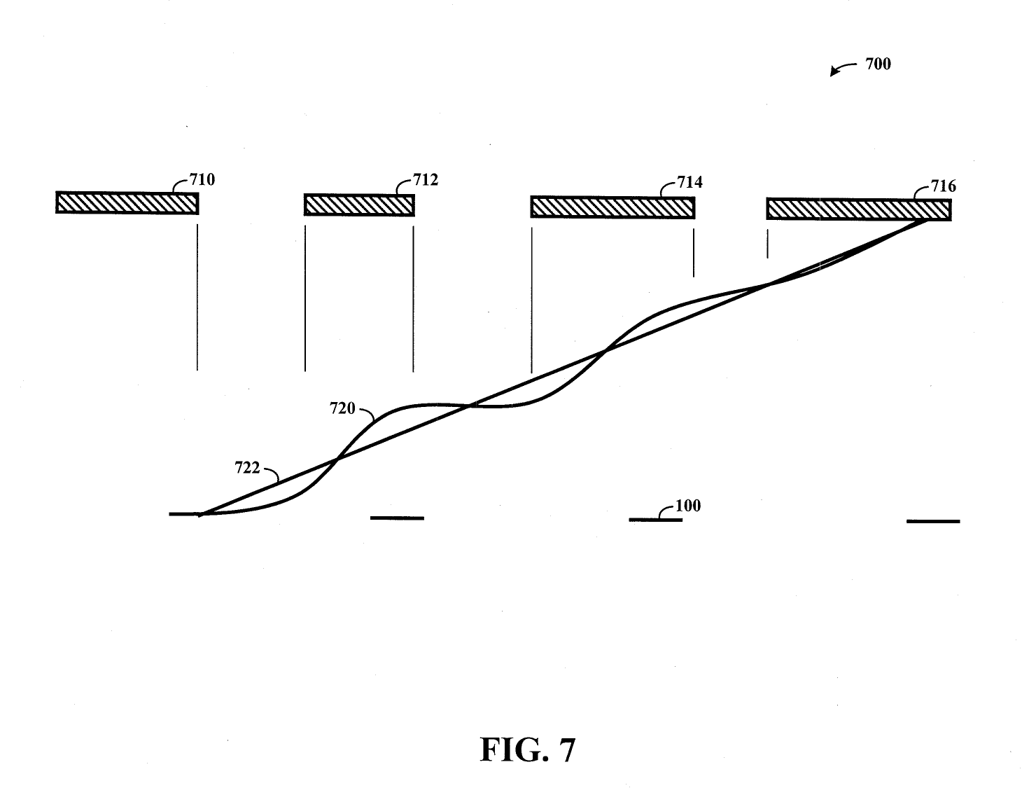

FIG. 7 shows a side view of a field plate cut to facilitate a desirable doping profile, in accordance with another example embodiment of the present invention; and

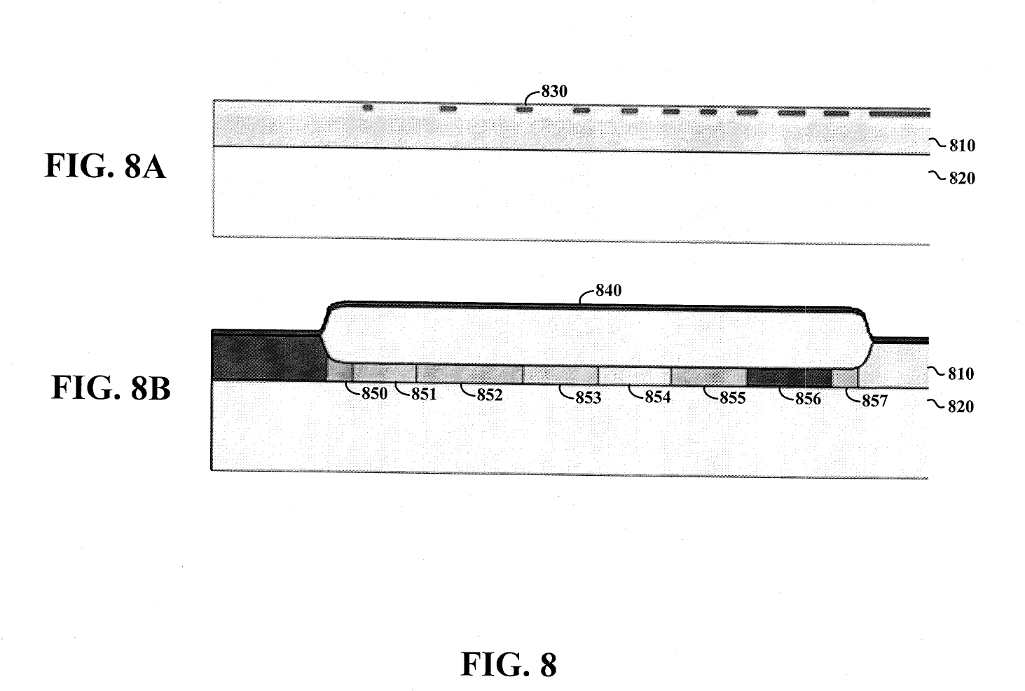

FIG. 8 shows a semiconductor device in different stages of manufacture involving doping implants to set a profile, in accordance with another example embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the invention including aspects defined in the claims. Furthermore, the term “example” as used throughout this document is by way of illustration, and not limitation.

The present invention is believed to be applicable to a variety of different types of circuits, devices and arrangements involving field plates. While the present invention is not necessarily limited in this context, various aspects of the invention may be appreciated through a discussion of related examples.

According to an example embodiment, a circuit includes a field plate having one or more patterned edges that exhibit an electric field that varies over distance, with the patterned edges effecting gradual field variation. In some implementations, the patterned edges of the field plate include comb-like features in-plane with the field plate, which mitigate electric field peaks that tend to be induced by transitions. In other implementations, the patterned edges include internal edges defining an opening that is internal to outer edges of the field plate.

The thickness and the dielectric permittivity of the dielectric that separates the field plate from the underlying active silicon can be set to achieve strong interaction between the field plate and active silicon, while thick enough to support (with some margin) the voltage required for the particular application. Non-uniform dielectric thickness between the field plate and the active silicon is used to attain strong interaction while supporting voltage as discussed above, relative to voltage drop within the device in which the field plate is used (e.g., thicker dielectric is used to support areas of higher voltage drop). In some implementations, the dielectric thickness increases about linearly relative to an increase in voltage drop (e.g., from source to drain).

The field plate-based circuits as discussed herein can be implemented with a variety of different types of devices, and with different types of materials. Various embodiments are directed to field plate-based circuits formed in and/or over bulk silicon. Other embodiments are directed to applications in silicon-on-insulator (SOI) structures. Still other embodiments are directed to non-silicon semiconductor materials, such as silicon carbide (SiC) or III-V materials (e.g., gallium nitride (GaN)).

In various embodiments, a field plate as discussed herein includes two or more plate portions contiguously linked with a gate plate portion or a separate gate portion. One or both of such portions employ patterned characteristics that facilitate the application of a varying electric field, as discussed above. In many implementations, the two or more plate portions extend beyond and/or overlap other plate portions, relative to an active region to which a field is applied by the field plates.

Another example embodiment is directed to a circuit device including a substrate having an active region, a dielectric material on the substrate, and a contiguous field plate having a patterned end region and an opposite end region (e.g., regions near or at opposing ends along the length of a field plate). The patterned end has at least one opening defined by edges of the field plate, such as a two-sided or three-sided opening at an edge of the patterned end, or an internal opening within outer edges of the field plate.

The field plate is configured to couple a field to the active region in response to a voltage applied to the field plate, as follows. The patterned end, relative to the opposite end, is configured with less material per square area (e.g., surface density per unit area) relative to the opposite end (due to the opening(s)), and applies a field to the active region that is less than a field coupled to the active region via the opposite end. For instance, considering a symmetric shape such as a polygon, material removed from a patterned end of the shape configures the shape for applying a varying field.

In a more particular embodiment, a device having a field plate as discussed herein includes an overlapping field plate that extends over and beyond a patterned field plate as discussed above. The overlapping field plate includes an overlapping portion which is separated from the active region by the patterned end (and perhaps more) of the patterned field plate. The overlapping field plate also includes an extended end that extends laterally beyond the patterned field plate, relative to an orientation in which the patterned field plate is over/above the active region (e.g., as shown by way of example in the figures). The overlapping portion couples a field to the active region via said field plate, and the extended portion couples a field to a portion of the active region without passing through the patterned field plate (e.g., directly via an insulating material separating the overlapping field plate from the active region).

Various patterns may be implemented in connection with the field plates as discussed herein. In some embodiments a patterned end of a field plate has a periphery that includes a portion that extends non-linearly from an outer edge to an interior portion of the field plate, and back to an outer edge of the field plate to define at least one of the at least one openings. In other embodiments, a patterned end of a field plate has at least one internal opening with sidewalls defined by conductive material of the field plate, and within edges of the conductive material that define a periphery of the conductive material. The opening may also be defined by a slit formed in a conductive material of the field plate, which remains after a portion of the conductive material has been cut. Various field plates have a combination of different types of openings therein.

Turning now to the Figures, FIG. 1 shows a cross-sectional view of a semiconductor device 100 with a patterned field plate 110, according to another example embodiment of the present invention. The field plate 110 is formed over a dielectric material 120 on an active region 130. Another layer 140 (e.g., a buried oxide, or bulk substrate) underlies the active region 130. Additional material 150 (e.g., interlayer dielectric) is formed over the field plate 110.

The field plate 110 includes a patterned area at 112, shown in a cut-away portion of the device 100. The patterned area 112 is shown having a particular shape, which may be tailored (in other embodiments) to suit particular applications. Generally, the patterned area 112 serves to facilitate the application of a gradually-reducing field to the underlying active region 130 via the dielectric 120, progressing to the end/tip area 113 of the patterned region. Further, this reduced field (left to right, as shown) can be effected with a constant thickness of the dielectric 120. In addition, the amount of material/surface density in different locations can be used to define the field applied to the active region 130.

Referring to FIG. 2, a variety of patterned shapes are shown from a top-down perspective, for implementation with field plates in accordance with one or more example embodiments. The exemplary patterns in the field plates 200, 210 and 220 as shown in FIGS. 2A, 2B and 2C apply a reduced field near the end/tip of the respective patterns (moving left to right as shown), relative to the rest of the field plate. Each of the field plates 200, 210 and 220 may be implemented in a manner such as shown in FIG. 1, as field plate 110.

The size of the field plates 200, 210 and 220 and relative dimensions of the patterned end regions as shown may vary, depending upon the implementation. By way of example, field plate 200 is labeled with widths W₁ and W₂, and length L. In some embodiments, the relative dimensions of the field plate 200 are as follows: 0.1×tₒₓ≦w₁≦tₒₓ, w₁≦w₂≦w₁×10, where tₒₓ is the thickness of a dielectric underlying the field plate 200 (e.g., of dielectric 120 underlying field plate 110 in FIG. 1). In other embodiments, the fingers of the field plate 200 are smaller in size than the underlying dielectric thickness, whereas the width of an inwards pointing feature is slightly wider. Exemplary finger length is between 0.5 μm and 5 μm.

The patterned shapes of the respective field plates 110, 200, 210 and 220 as shown in FIGS. 1 and 2 can be manufactured using one or more of a variety of approaches, with one or more of a variety of materials. In some embodiments, a mask and etch process, such as used to form other features in a semiconductor device (e.g., concurrently), can be used to form the field plates. Such an approach can be implemented as part of a MOSFET manufacturing process, on bulk silicon or silicon-on-insulator (SOI) substrates. The field plates include a conductive material, such as polysilicon or other conductive material (e.g., as part of a Metal1, or Metal2 layer).

The various field plates and related devices as discussed herein can be implemented in a variety of different devices. In some implementations, a field plate as discussed herein is implemented in a high voltage application, such as those involving a breakdown voltage of over about 100V, with applications including light-emitting diode (LED) drivers, compact fluorescent lamp (CFL) drivers, and battery chargers.

Other embodiments are directed to a circuit having a field plate having a patterned end region and separated from an active region by a dielectric material as discussed herein, further implemented with varying (e.g., linearly increasing) lateral doping. The variable doping works together with the patterned end region to set the bias, or field, applied by the field plate to the active region. Other embodiments are directed to a field plate as discussed herein, implemented with an underlying dielectric having a varied thickness that also affects the field applied by the field plate to the active region. Still other embodiments are directed to a patterned field plate as discussed herein, implemented with both variable doping and a variable thickness dielectric, which function together to set the field applied by the field plate to the active region.

Turning now to FIG. 3, three field plate patterned shapes are shown from a top-down perspective (e.g., similar to FIG. 2), for implementation with field plates in accordance with one or more example embodiments. The exemplary patterns in the field plates 300, 310 and 320 as shown in FIGS. 3A, 3B and 3C have patterned or unpatterned edges and/or internal openings that facilitate the application of a reduced field near an end or tip of the respective plates, relative to an opposite end of the field plate (with a reduced field applied near the right end of the field plates 300, 310 and 320 as shown, relative to the left end). Each of the field plates 300, 310 and 320 may be implemented in a manner such as shown in FIG. 1, as field plate 110.

The shape, location and arrangement of the patterned edges and internal regions (openings) of the field plates 300, 310 and 320 may vary, depending upon the implementation and desired field effect. For instance, a patterned edge and/or opening can be selectively formed in a field plate to compensate for electric field peaks caused by non-idealities in the doping profile. Similarly, a field plate may be configured with patterned edges and/or openings that effect a field relative to an underlying dielectric in a manner that is similar to that as discussed above in connection with FIG. 2 (e.g., dielectric 120 underlying field plate 110 in FIG. 1). Similarly, the patterned shapes of field plates 300, 310 and 320 as shown in FIG. 3 can be manufactured using one or more of a variety of approaches, with one or more of a variety of materials, in manners including those discussed in connection with FIGS. 1 and 2 above.

FIG. 4 shows a device 400 having a patterned field plate configured to apply a varied electric field to an underlying semiconductor region (e.g., an active/doped region), in accordance with another example embodiment of the present invention. The device 400 includes an active layer 410 that is formed over an underlying layer 420, such as a bulk silicon layer or an oxide layer that forms a silicon-on-insulator structure with the silicon layer 410.

A dielectric layer 450 is formed on the active layer 410, and a patterned field plate 460 is formed on the dielectric layer. The field plate 460 may, for example, include one of the plates as shown in FIGS. 1-3, with a patterned end 461 having an edge and/or an internal opening (shown with 462 by way of example).

The active layer 410 includes a source electrode 430 over a source region 432, drain electrode 440 and a channel-type region between and extending below and laterally beyond the overlying field plate 460. The patterned end of the field plate 460 has less material, relative to an opposite end 463. Accordingly, with a voltage applied to the field plate 460, the patterned end 461 applies less of a field to the portion of the active layer 410 underlying the patterned end, relative to a field applied by the opposite end 463 to the portion of the active layer underlying the opposite end. In some instances, the opposite end 463 acts as and/or includes a gate.

In various embodiments, the device 400 includes another field plate 470 that overlies and extends laterally beyond the field plate 460, and may further be separated from the field plate 460 by a dielectric material 472. The field plate 470 includes an overlapping portion 474 and an extended portion 476. The extended portion 476 applies a field directly to the active region 410 (e.g., via an intervening dielectric).

FIG. 5 shows a cross-sectional view of a field plate device 500 having an opening patterned in a field plate and offset from an underlying dielectric transition, in accordance with another example embodiment of the present invention. The device 500 includes a field plate having field plate portions 510 and 520, with an opening 515 formed therebetween and defined by edges of the field plate. The field plate is separated from an underlying substrate 530 by a dielectric material 540 having a step transition 542 (e.g., a LOCOS edge), with a thicker portion generally below field plate portion 520, and a thinner portion generally below field plate portion 510. In other embodiments, the step transition is a relatively smooth step (e.g., with certain transitions being of a lesser degree, such as between about 10 and 80 degrees from vertical). The opening 515 is aligned about vertically over the transition 542 (e.g., shown slightly offset over the thin portion of the dielectric material 540), to facilitate a smooth transition in field applied to a drift region in the substrate 530.

FIG. 6 shows a cross-sectional view of a field plate device 600 having an opening patterned in a field plate and over an underlying dielectric transition, in accordance with another example embodiment of the present invention. The device 600 includes a field plate having field plate portions 610 and 620, with an opening 615 formed therebetween and defined by edges of the field plate. The field plate is separated from an underlying substrate 630 by a dielectric material 640 having a step transition 642, with a thicker portion generally below field plate portion 620, and a thinner portion generally below field plate portion 610. The opening 615 is aligned about vertically over the transition 642 and extending laterally beyond the transition, to facilitate a smooth transition in field applied to a drift region in the substrate 630.

The position and width of the openings in a field plate, such as shown in FIGS. 5 and 6, can be set based upon an underlying dielectric material transition as shown and/or based upon a doping profile in an underlying drift region. In one example, the opening width is set between 1-5 times the thickness of the underlying dielectric. Accordingly, the openings can be made to reduce a field applied by the field plate to the drift region gradually, leading up to a transition (e.g., by field plate portion 510 in FIG. 5), to smooth an otherwise abrupt transition due to dielectric thickness changes and/or doping profile changes.

FIG. 7 shows a side view of a mask that facilitates a desirable doping profile, in accordance with another example embodiment of the present invention. Openings between portions 710, 712, 714 and 716 facilitate an underlying doping profile that can be used to suppress non-ideal characteristics, and relieve capacitive coupling in regions in which a doping profile is insufficiently increasing relative to a desirable coupling to a drift region. Plot 720 shows resulting profile characteristics that are used to facilitate/achieve close to an ideal linear profile 722.

FIG. 8 shows a semiconductor device at different stages of manufacture, and involving doping to set a profile, in accordance with another example embodiment of the present invention. Beginning with FIG. 8A, a silicon layer 810 on an underlying insulator 820 (e.g., in a silicon-on-insulator (SOI) application) is doped in several areas as shown (e.g., using a mask as discussed above), with regions 830 labeled by way of example.

In FIG. 8B, an oxide 840 has been formed (e.g., via local oxide of silicon (LOX)) over the silicon layer 810. The device has also been annealed to form a generally linearly increasing doping concentration moving laterally from left to right, as represented by regions 850-857. When employed with a patterned field plate such as discussed above and/or shown in the figures, openings in the field plate are made to facilitate a smooth transition relative to the actual doping profile (e.g., to compensate for non-idealities in the doping profile), as may be relevant to doping concentration transitions for regions 850-857. In particular, openings can be formed in an overlying field plate near the lower doping concentration regions (e.g., near region 850, relative to region 857), at which the spacing between implants (as shown in FIG. 8A) is larger.

The field plate openings as shown in and described above in connection with FIGS. 5-8 are located about vertically over either a step transition of dielectric material, a doping profile transition or both. In this context, an opening that is about vertically over a transition or transitions is directly over, or adjacent (e.g., within a lateral distance corresponding to a thickness of underlying dielectric material), in a manner that is sufficient to control coupling of the field plate in a manner that facilitates a smoother field transition in an underlying drift region. Such an opening may also be arranged over both a dielectric material transition and a doping profile transition. In addition, two or more openings may be arranged about vertically over (directly over or laterally adjacent) a single transition, and several such openings may be employed over laterally adjacent transitions underlying the field plate.

Based upon the above discussion and illustrations, those skilled in the art will readily recognize that various modifications and changes may be made to the present invention without strictly following the exemplary embodiments and applications illustrated and described herein. For example, other arrangements of field plates different than those shown or discussed above may be implemented with various embodiments, with ends or edges patterned to effect the application of a field by the field plate that is smooth or otherwise transitioned along the field plate. Similarly, the embodiments described with particular materials such as silicon may be implemented with other types of active regions. Such modifications do not depart from the true spirit and scope of the present invention, including that set forth in the following claims.

What is claimed is:

1. A circuit device comprising:
a semiconductor substrate having an active region;
a dielectric material on the substrate; and
a field plate having contiguous first and second end regions, the second end region being patterned and having at least one opening therein defined by edges of the field plate, the field plate being configured to couple a field to the active region in response to an applied voltage, the field coupled to the active region via the second end region having a lower strength relative to the field coupled to the active region via the first end region.

2. The device of claim 1, further including an overlapping field plate having
an overlapping portion separated from the active region by the second end region of said field plate and configured to couple a field to the active region via said field plate, in response to a voltage applied thereto, and
an extended portion extending laterally beyond the second end region of said field plate and configured to couple a field to a portion of the active region directly via the dielectric material, in response to a voltage applied thereto.

3. The device of claim 1,
further including an overlapping field plate having
an overlapping portion separated from the active region by the second end region of said field plate and configured to couple a field to the active region via said field plate, in response to a voltage applied thereto, and
an extended portion extending laterally beyond the second end region of said field plate and configured to couple a field to a portion of the active region directly via the dielectric material,
wherein the second end region of said field plate is configured, with the overlapping portion of the other field plate, to respond to a voltage applied to said field plate by coupling a field to the active region via the second end region and overlapping portion that is less than a field coupled to the active region via the first end region and greater than a field coupled to the field by the extended portion.

4. The device of claim 1, further including an upper field plate over said field plate and extending laterally from an overlapping portion over the second end region to an extended portion laterally adjacent the second end region, said field plate separating the overlapping portion of the upper field plate from the active region and not separating the extended portion of the upper field plate from the active region.

5. The device of claim 1,
further including a buried insulator layer, and
wherein the substrate is a silicon substrate on the buried insulator, with the silicon and buried insulator forming a silicon-on-insulator substrate.

6. The device of claim 1, wherein the second end region has a periphery that includes a portion that extends non-linearly from an outer edge of the field plate to an interior portion of the field plate, and back to an outer edge of the field plate to define at least one of the at least one openings.

7. The device of claim 1, wherein the second end region has at least one internal opening with sidewalls defined by the field plate and within edges of the field plate that define a periphery of the field plate.

8. The device of claim 1, wherein the at least one opening includes a slit defined by edges of the field plate that remain after a portion of the field plate has been cut.

9. The device of claim 1, wherein the second end region has at least two openings including
an opening having sidewalls defined by a periphery of the second end region that includes a portion that extends non-linearly from an outer edge of the field plate to an interior portion of the field plate, and back to an outer edge of the field plate, and
an internal opening having sidewalls defined by the field plate and within edges of the field plate that define a periphery of the field plate.

10. The device of claim 1, wherein
the field plate has an outer perimeter defined by edges of the field plate and including any openings defined by the edges, and
the density per unit area of the second end region is less than the density per unit area of the first end region, the respective densities being configured to set the relative field applied to the active region by the first and second end regions.

11. The device of claim 1, further including a gate connected to the field plate, the field plate extending in a lateral direction away from the gate and over the drift region.

12. The device of claim 1, wherein
the dielectric material includes a step transition in which the thickness of the dielectric material between the substrate and the field plate changes, and
at least one of the openings in the patterned second end region is arranged about vertically over the step transition.

13. The device of claim 1, wherein
the active region is doped with a doping profile having a near-linear lateral doping profile that deviates from a linear profile, and
at least one of the openings in the patterned second end region is arranged about vertically over a transition in the doping profile.

14. The device of claim 1, wherein
the dielectric material includes a step transition in which the thickness of the dielectric material between the substrate and the field plate increases,
the active region is doped with a doping profile having a transition in the lateral doping profile, and
at least one of the openings in the patterned second end region is arranged about vertically over a transition in the doping profile, and at least one of the openings in the patterned second end region is arranged about vertically over the step transition.

15. An integrated circuit device comprising:
a semiconductor substrate;
in the substrate, source/drain electrodes and a channel region separating the source-drain electrodes;
a dielectric material on the substrate;
a gate on the dielectric material and laterally adjacent one of the source/drain electrodes, the gate being configured to apply a bias to the channel region adjacent the one of the source/drain electrodes; and
a field plate having first and second contiguous end regions, the first end region being adjacent and coupled to the gate the second end region being patterned and having at least one opening therein defined by edges of the field plate, the field plate being configured to couple a field to the channel region in response to an applied voltage for flowing current between the source/drain regions, the field coupled to the active region via the second end region having a lower strength relative to the field coupled to the active region via the first end region.

16. The device of claim 15, wherein the field plate is configured to shield a p-n junction at the channel region from electrical disturbances.

17. The device of claim 15, further including an overlapping field plate having an overlapping portion configured to couple a field to the active region via said field plate and an extended portion extending laterally beyond the second end region, the dielectric material extending between the field plates and between the extended portion and the active region, the extended portion being configured to couple a field to the active region directly via the dielectric material in response to a voltage applied thereto.

18. The device of claim 15,
further including an overlapping field plate having an overlapping portion configured to couple a field to the active region via said field plate and an extended portion extending laterally beyond the second end region, the dielectric material extending between the field plates and between the extended portion and the active region, the extended portion being configured to couple a field to the active region directly via the dielectric material in response to a voltage applied thereto,
wherein the field plates are respectively configured, relative to the active region, to apply a field to the active region, via the dielectric material, that decreases linearly from a portion of the active region below the first end region, through a portion of the active region below the second end region, and to a portion of the active region below the extended portion of the overlapping field plate.

19. The device of claim 15, further including a buried insulator layer, wherein the source/drain electrodes and the channel region are formed in the substrate and on the buried insulator layer.

20. The device of claim 15, wherein the second end region has a periphery that includes a portion that extends non-linearly from an outer edge of the field plate to an interior portion of the field plate, and back to an outer edge of the field plate to define at least one of the at least one openings at an outer edge of the field plate.

21. The device of claim 15, wherein the second end region has at least one internal opening with sidewalls defined by the field plate and within edges of the field plate that define a periphery of the field plate.

22. A method for manufacturing an integrated circuit device, the method comprising:
forming an active region in a semiconductor substrate;
forming a dielectric layer on the substrate;
forming a contiguous field plate on the dielectric layer and extending from a first end region to a second end region, by defining at least one opening in the second end region to configure the field plate to, in response to an applied voltage, couple a field to the active region via the first and second end regions, the field being applied via the second end region having a lower strength relative to the field coupled to the active region via the first end region.
